(19) United States
(12) Patent Application Publication
(10) Pub. No.: US 2021/0243904 A1
(43) Pub. Date: Aug. 5, 2021

(54) DIRECT INKJET PRINTING OF INFRASTRUCTURE FOR INTEGRATED CIRCUITS

(71) Applicants: NANO-DIMENSION TECHNOLOGIES LTD., Nes Ziona (IL); The IP Law Firm of Guy Levi, LLC, Wyckoff, NJ (US)

(72) Inventor: Avishai Ya'ary, Hod Hasharon (IL)

(21) Appl. No.: 16/972,602

(22) PCT Filed: Jun. 4, 2019
(86) PCT No.: PCT/US19/35322

§ 371 Date: Dec. 6, 2020

Related U.S. Application Data
(60) Provisional application No. 62/680,062, filed on Jun. 4, 2018.

(51) Int. Cl. H05K 3/46; B41M 5/00; G05B 19/4099; H05K 3/12; H05K 3/40

(52) U.S. Cl. CPC H05K 3/4664; B41M 5/0047; G05B 19/4099; H05K 3/125; H05K 2203/0502; G05B 2219/49005; G05B 2219/45026; H05K 2203/013; H05K 3/4007

(57) ABSTRACT

The disclosure relates to methods for direct ink jet printing of printed circuits' infrastructure. Specifically, the disclosure relates to methods for direct inkjet printing of heatdissipation elements and sockets for use in printed circuit boards (PCBs), flexible printed circuits (FPCs) and high-density interconnect (HDI) printed circuits.

### BACKGROUND

The disclosure is directed to methods for ink jet printing of printed circuits' infrastructure. Specifically, the disclosure is directed to methods for direct inkjet printing if heat dissipation elements and sockets for use in printed circuit boards (PCBs), flexible printed circuits (FPCs) and high-density interconnect (HDI) printed circuits.

High power electronic components such as central processing units (CPU) and graphics processing units (GPU), and power supply units (PSU) generate a large amount of heat during operation and usually are provided with their own cooling units. However, to increase computing performance for example by overclocking (in other words increasing clock frequency above the standard frequency that the manufacturer used) in stringent packaging constraint, many of these components generate extra heat that cannot be adequately dissipated by the cooling systems provided (e.g., cooling fans).

Conventional cooling solutions include placing a heat sink or heat pipe in contact with a surface of the component, which draws (or spreads) heat away from the electronic component via conduction. The heat is then dissipated by convection, possibly in conjunction with the one or more fans provided, which force air over the heat sink or heat pipe. Likewise, using two-phase heating pipes' systems are usually limited by the size of the capillaries used as vapor pumps and therefore, the distance to the condenser.

The heat needs to be dissipated to avoid overheating the component. Conventional cooling solutions include placing a heat sink or heat pipe in contact with a surface of the component, which draws heat away from the electronic component via conduction. The heat is then dissipated by convection, possibly in conjunction with one or more fans that force air over the heat sink or heat pipe. Efficient cooling solutions enable electronic components to operate at higher speeds, thereby making the overall system more efficient.

Current designs for heat sinks and heat pipes are limited in that these devices only draw heat away from a top surface of the electronic component. For example, the heat is transferred to the heat sink through conduction at the contact surface between the heat sink and the component. Increasing the size (i.e., volume) of the heat sink is not effective after a certain point because the additional material added to the heat sink is further and further away from the contact surface. The steady state conductive properties of the heat sink material limit the ability of the heat sink to draw any additional heat away from the component. Thus, there is a need for addressing this issue and/or other issues associated with the prior art.

In addition, it is beneficial to couple integrated circuits to PCBs as rapidly and economically as possible. Repeated manual loading and unloading of individual electronic device packages is possible. However, this procedure is slow, labor intensive and therefore expensive. Moreover, semiconductor devices must be handled carefully to avoid damage to the device and its package. Due to the fragility of integrated circuit devices and the electronic device packages, minimal (repeated) handling is also beneficial. For instance, the leads on an electronic device package may be damaged or bent while being inserted into a socket on a PCB if not aligned correctly with the socket. Even if aligned correctly, the leads may become worn through repeated insertion and removal from a socket.

The following disclosure addresses these shortcomings.

### SUMMARY

Disclosed, in various embodiments, are methods for inkjet printing of infrastructure elements for integrated circuits, such as, for example, heat-dissipation elements and sockets for use in printed circuit boards (PCBs), flexible printed circuits (FPCs) and high-density interconnect (HDI) printed circuits.

In an embodiment provided herein is an inkjet printing method for forming infrastructure element for an integrated circuit in a printed circuit board, the method comprising: providing a substrate; providing an ink jet printing system comprising: a first print head having: at least one aperture, a dielectric ink reservoir, and a first dispenser configured to supply the dielectric ink through the aperture; a second print head having: at least one aperture, a conductive ink reservoir, and a second dispenser configured to supply the conductive ink through the aperture; a conveyor, operably coupled to the first print head and to the second print head, configured to convey the substrate to the first and second print head; and a computer aided manufacturing (“CAM”) module, comprising: a processor; a non-volatile memory; and a set of executable instructions stored on the non-volatile memory configured, when executed to cause the processor to: receive a 3D visualization file representing the infrastructure element; using the 3D visualization file, generate a library comprising a plurality of files, each file representing a substantially 2D layer for printing of the infrastructure element; receive a selection of parameters related to the infrastructure element; and alter each of the substantially 2D layer file in the library based on at least one of the selection of parameters for printing at least one of a conducting portion and a dielectric portion of the infrastructure element; providing a dielectric ink composition and a conductive ink composition; using the CAM module, obtaining the generated file representing the plurality of substantially 2D layer of the infrastructure element for printing, the 2D layer comprising a pattern representative of the conductive inkjet ink and the dielectric inkjet ink, wherein the file obtained correspond to a first layer for printing; using the first print head, forming the pattern corresponding to the dielectric representation in the first layer of the infrastructure element for printing; curing the dielectric pattern; using the second print head, forming the pattern corresponding to the conductive representation in the first layer of the infrastructure element for printing; sintering the conductive pattern; and repeating the steps from obtaining the generated file, wherein the file obtained correspond to a subsequent layer to a precedent layer for printing, to the step of sintering the conductive layer to the completion of the library.

These and other features of the methods for direct printing of plated and/or filled vias with quadrilateral cross section in multilayered printed circuit boards, will become apparent from the following detailed description when read in conjunction with the figures and examples, which are exemplary, not limiting.

### BRIEF DESCRIPTION OF THE FIGURES

For a better understanding of the methods for direct ink jet printing of integrated circuits' infrastructure in multilayered printed circuit boards (PCBs) flexible printed circuits (FPCs) and high density interconnect printed circuits (HDI circuits), with regard to the embodiments thereof, reference is made to the accompanying examples and figures, in which:

FIG. 1 illustrates a top plan view schematic of ICs on PCB printed according to an embodiment;

FIG. 2, illustrates X-Z cross section of the top layer in the multi-layered PCB illustrated in FIG. 1;

FIG. 3, illustrates X-Z cross section of the multilayer PCB comprising the heat dissipation elements of the infrastructure along section A-A in FIG. 1;

FIG. 4, illustrates X-Z cross section of the top layer in the multi-layered PCB illustrated in FIG. 1 taken along section B-B; and

FIGS. 5 and 6 illustrate prior art sockets that can be printed using the methods described.

### DETAILED DESCRIPTION

Provided herein are embodiments of methods for inkjet printing if heat-dissipation elements and sockets for use in printed circuit boards (PCBs), flexible printed circuits (FPCs) and high-density interconnect (HDI) printed circuits.

The methods described herein can be used to form the printed circuit board (PCB) in a continuous and/or semi-continuous process using the inkjet printing device or using several passes. Using the methods described herein, dielectric material is used to form the board, which is typically formed separately and provided as a substrate for further printing of the conductive and dielectric layers on top of it, is eliminated and, using the methods described herein, it is possible to achieve higher component density, as well as increase flexibility in design.

Accordingly and in an embodiment, provided herein is an inkjet printing method for forming infrastructure element for an integrated circuit in a printed circuit board, the method comprising: providing a substrate; providing an ink jet printing system comprising: a first print head having: at least one aperture, a dielectric ink reservoir, and a first dispenser configured to supply the dielectric ink through the aperture; a second print head having: at least one aperture, a conductive ink reservoir, and a second dispenser configured to supply the conductive ink through the aperture; a conveyor, operably coupled to the first print head and to the second print head, configured to convey the substrate to the first and second print head; and a computer aided manufacturing (“CAM”) module, comprising: a processor; a non-volatile memory; and a set of executable instructions stored on the non-volatile memory configured, when executed to cause the processor to: receive a 3D visualization file representing the infrastructure element; using the 3D visualization file, generate a library comprising a plurality of files, each file representing a substantially 2D layer for printing of the infrastructure element; receive a selection of parameters related to the infrastructure element; and alter each of the substantially 2D layer file in the library based on at least one of the selection of parameters for printing at least one of a conducting portion and a dielectric portion of the infrastructure element; providing a dielectric ink composition and a conductive ink composition; using the CAM module, obtaining the generated file representing the plurality of substantially 2D layer of the infrastructure element for printing, the 2D layer comprising a pattern representative of the conductive inkjet ink and the dielectric inkjet ink, wherein the file obtained correspond to a first layer for printing; using the first print head, forming the pattern corresponding to the dielectric representation in the first layer of the infrastructure element for printing; curing the dielectric pattern; using the second print head, forming the pattern corresponding to the conductive representation in the first layer of the infrastructure element for printing; sintering the conductive pattern; and repeating the steps from obtaining the generated file, wherein the file obtained correspond to a subsequent layer to a precedent layer for printing, to the step of sintering the conductive layer to the completion of the library.

The terms “infrastructure”, and/or “infrastructure element” and/or “element of infrastructure” as used herein, generally refers to a physical component that provides power and/or conduits configured to enable, sustain, or enhance operation of the integrated circuits and other components (e.g., GPU) coupled to the board. An infrastructure element may comprise a heat pipe, a (moisture) condenser, a cooling pad, a vapor chamber a power socket, a USB socket and the like. Infrastructure does not however, include cooling fans.

In an embodiment, the term “dispenser” is used to designate the device from which the drops are dispensed. The dispenser can be, for example an apparatus for dispensing small quantities of liquid including micro-valves, piezoelectric dispensers, continuous-jet print-heads, boiling (bubblejet) dispensers, and others affecting the temperature and physico-chemical properties of the fluid flowing through the dispenser.

A more complete understanding of the components, methods, and devices disclosed herein can be obtained by reference to the accompanying drawings. These figures (also referred to herein as “FIG.”) are merely schematic representations based on convenience and the ease of demonstrating the present disclosure, and are, therefore, not intended to indicate relative size and dimensions of the devices or components thereof, their relative size relationship and/or to define or limit the scope of the exemplary embodiments. Although specific terms are used in the following description for the sake of clarity, these terms are intended to refer only to the particular structure of the embodiments and examples selected for illustration in the drawings, and are not intended to define or limit the scope of the disclosure. In the drawings and the following description below, it is to be understood that like numeric designations across different figures refer to components of like function. [00023] Likewise, cross sections are referred to on normal orthogonal coordinate apparatus having XYZ axis, such that Y axis refers to front-to-back, X axis refers to side-to-side, and Z axis refers to up-and-down.

As indicated, the infrastructure element can be, for example passive heat spreader (PHS) such as, at least one of: a cooling pad, a heat-pipe (for example, a two-phase heat pipe e.g. a thermosyphon, referring to a tubular metallic structure, consisting of an evaporator and a condenser sections), a (moisture) condenser, a wick (e.g., to provide the capillary action needed to drive cooling liquid against gravity), a cooling platform, and a vapor chamber.

For example, as illustrated in FIGS. 2, and 3 the heat sink can comprises a radiation fin module (not shown), a plurality of heat pipes 205ᵢ and a metal bottom block 203. The metal bottom block 203 is adapted for direct contact with a first heat source 101 (e.g., GPU, LED), for enabling absorbed heat energy to be transferred by the heat pipe(s) 205ᵢ to the radiation fin module(s) (not shown) for quick dissipating into the outside open air. As illustrated in FIG. 3, the heat pipes 205ᵢ can terminate at a hollow intermediate layer 130, which can be in fluid (or gas, or air) communication with a ventilation source, for example a fan that will create airflow through the hollow/empty layer. Additionally or alternatively, the heat pipes 205ᵢ can terminate at the basal (or apical, in other words, external) layer 105 of the PCB (interchangeable with FPC and HDIPC). The heat pipes 205ᵢ can be direct extensions with to metal bottom block 203, rather than being bonded (grazed) with a solder paste, thus creating a better connection.

In an embodiment, condenser 111, 112, can be printed directly, for example on at least the basal layer 105 (111) and the intermediate hollow layer 130 (112). Two-phase heat pipe can be directly printed, whereby heat can be transferred through the phase change of a liquid to vapor and back to liquid, whereby the liquid is passively passed from the evaporator e.g., raised platform 201 to the condenser 111, 112 via capillary action. In certain embodiments, the heat pipes are plated with conductive ink composition that can assist in wetting of the heat transfer liquid thus facilitating the capillary action. In an embodiment, condensers 111, 112, can be a fin stack printed directly using the methods and systems disclosed herein.

Furthermore, heat pipes (or plated/hollow micro vias) 205ᵢ, and/or 206ₚ, can be pipes plated with conductive ink composition, that are configured to operate as sintered (heat) wicks, and/or printed directly as grooved internal cross section, adapted to operate as grooved wicks. Using the methods described herein, based on the heat transfer coefficient of the sintered conductive ink composition and/or the cured dielectric ink composition, it is possible to design the proper diameter (internal surface area) that would enable dissipating the heat from the heat source under the required performance parameters. These and other factors can be used in the parameters used by the CAM module to translate the 3D file of the IC heat sink assembly (in other words, the platform, heat pipes, condensers, termination points, pipe length and the like), and appended as a metadata in the library and/or attached to each substantially 2D layer file before or after it is parsed to its conductive and dielectric (insulating) portions.

For example, the heat source can be at least one of a Quad Flat Pack (QFP) package, a Thin Small Outline Package (TSOP), a Small Outline Integrated Circuit (SOIC) package, a Small Outline J-Lead (SOJ) package, a Plastic Leaded Chip Carrier (PLCC) package, a Wafer Level Chip Scale Package (WLCSP), a Mold Array Process-Ball Grid Array (MAPBGA) package, a Quad Flat No-Lead (QFN) package, and a Land Grid Array (LGA) package, a dual-in-line package (DIP), a light emitting diode (LED), a graphic processing unit (GPU) a central processing unit (CPU) and an adjacent PCB.

As illustrated in FIG. 3, metal block disc 202, can be printed as a circular disc and can extend at an angle off normal basally from metal block disc 202, thereby, for example distributing heat dissipation away from adjacent components that may be sensitive. In certain embodiments, the systems disclosed can calculate the angle of the heat sink portion extending basally from metal block disc 202 (or other bases), which can dissipate the heat optimally relative to other components.

In yet another embodiment, raised component 104, for example GPU, can be coupled to the top layer 100 with pins 205ᵢ and ball grid array (BGA) 107ₙ, In these embodiments, it is possible to directly print the proper conductive ink pattern that will remain in contact with the basal side of raised component 104, as well as direct printing of the BGA. Using the systems and methods described, it is therefore possible to maintain intimate contact among all the heat sink assembly component and the raised component. The electrically conductive elements such as the pins 205ᵢ comprise solder balls 107ₙ in electrical communication with and attached to a contact pad, or can merely be a solder ball placed directly upon, or in electrical communication with, the termination point of a selected circuit trace 110. Alternatively, conductive balls e.g., 107ₙ can be made of a conductive-filled epoxy material having specifically preselected conductive qualities. The conductive elements or balls can be printed directly in a grid array pattern wherein the conductive elements or solder balls are of a preselected size or sizes and are spaced from each other at one or more preselected distances, or pitches. Hence, “fine ball grid array” (FBGA) can be used to refer to a printed BGA pattern having what are considered to be relatively small conductive elements or solder balls being spaced at very small distances from each other resulting in dimensionally small spacing or pitch. As generally used herein, the term “ball grid array” (BGA) encompasses fine ball grid arrays (FBGA) as well as BGAs. Accordingly and in an embodiment, the 2D pattern representative of the conductive ink printed using the methods described herein, is configured to fabricate interconnect (in other words, solder/contact) balls.

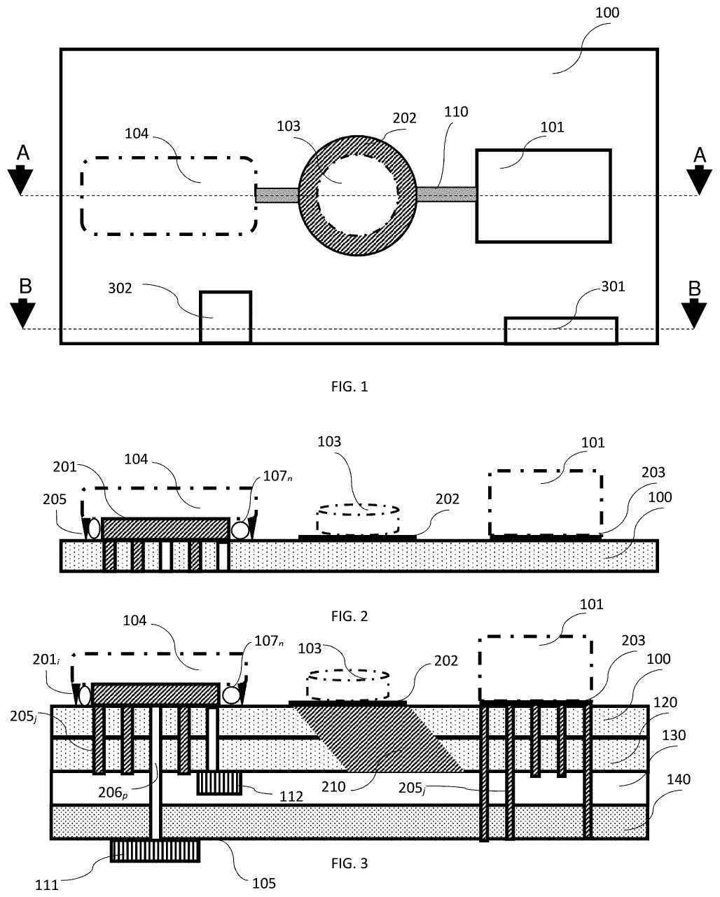

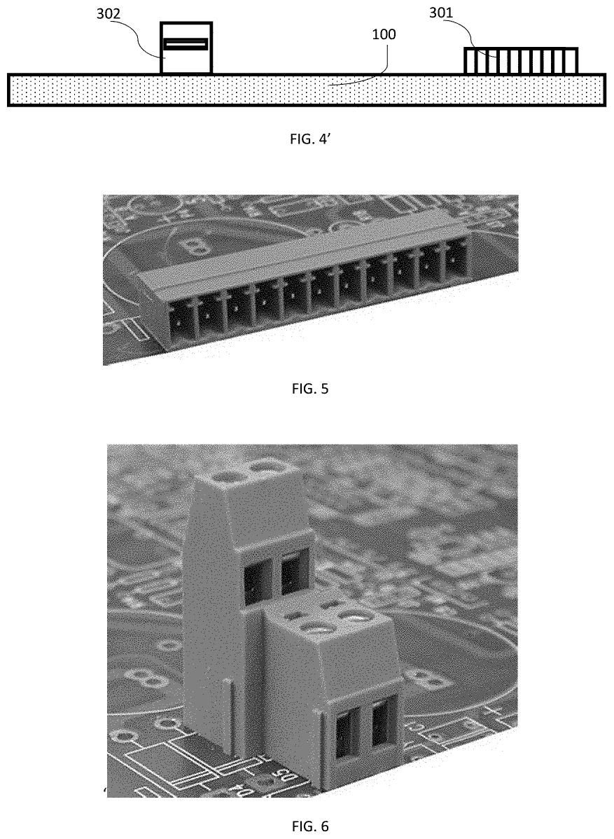

In an embodiment, the methods provided can be used to directly print the sockets to which the ICs are coupled. These can be those sockets illustrated in FIGS. 5, and 6, or other sockets. By integrating the printing of the sockets to the fabrication of the PCB, FPC, or HDIPC, it is possible to customize the necessary friction to maintain the contact between the various (IC) components and the board. Accordingly, the socket is at least partially disposed in the printed circuit board. Although as illustrated in FIG. 4, the sockets 301, 302 are provided in a row, these are provided for illustrative purposes only. For instance, it is possible to arrange the sockets in an array of multiple rows and columns if desired, or as needed. Further, single or multiple sockets may be arranged on the printed circuit board in any suitable pattern or position as is found advantageous for a particular electronic device package or purpose. In the embodiment of the invention illustrated in FIGS. 1-4 it is within the scope of the disclosure to provide the printed circuit board 10 with an edge connector (301) and a side opening (not shown). In another embodiment, the pads and fiducials used to connect the sockets to the upper layer 100 of the PCB, can be printed (if the fiducials are necessary at all) at the same time over the upper layer 100 of the printed circuit board.

The method of forming the PCB's can comprise a step of providing a substrate (e.g., a peelable substrate such as a film). The print head (and derivatives thereof; are to be understood to refer to any device or technique that deposits, transfers or creates material on a surface in a controlled manner) depositing the dielectric ink, can be configured to provide the ink droplet(s) upon demand, in other words, as a function of various process parameters such as conveyor speed, desired PCB sublayer thickness, whether the via, or heat pipe is filled or plated, or their combination.

The substrate, which can be, for example removable or peelable, can also be a relatively rigid material, for example, glass or crystal (e.g., sapphire), Alternatively, the substrate may be a flexible (e.g., rollable) substrate (or film) to allow for an easy peeling of the substrate from the PCB, for example, poly(ethylenenaphthalate) (PEN), polyimide (e.g. KAPTONE® by DuPont), silicon polymers, poly(ethyleneterphtalate) (PET), poly(tetrafluoroethylene) (PTFE) films etc.

Other functional steps (and therefore means for affecting these steps) may be taken before or after the first or second print heads (e.g., for sintering the conductive layer). These steps may include (but not limited to): a heating step (affected by a heating element such as a chuck, or hot air); photobleaching (using e.g., a UV light source and a photo mask); drying (e.g., using vacuum region, or heating element); (reactive) plasma deposition (e.g., using pressurized plasma gun and a plasma beam controller); cross linking (e.g., not multifunctional acrylates and/or methacrylates) by selectively initiated through the addition of a photoacid such as [4-[(2-hydroxytetradecyl)-oxyl]phenyl-phenyliodonium hexafluoro antimonate to a polymer solutions prior to coating or used as dispersant with the metal precursor or nanoparticles); annealing, or facilitating redox reactions.

Formulating the conductive and/or dielectric ink composition(s), may take into account the requirements, if any, imposed by the deposition tool and the surface characteristics (e.g., at least one of hydrophilic or hydrophobic, and the surface energy) of the (optionally removable) substrate. Using ink-jet printing with a piezo head, the viscosity of either the conductive ink and/or dielectric ink (measured at 20° C.) can be, for example, not lower than about 5 cP, e.g., not lower than about 8 cP, or not lower than about 10 cP, and not higher than about 30 cP, e.g., not higher than about 20 cP, or not higher than about 15 cP. The conductive ink, and/or dielectric ink can each be configured (e.g., formulated) to have a dynamic surface tension (referring to a surface tension when an ink-jet ink droplet is formed at the print-head aperture) of between about 25 mN/m and about 35 mN/m, for example between about 29 mN/m and about 31 mN/m measured by maximum bubble pressure tensiometry at a surface age of 50 ms and at 25° C. The dynamic surface tension can be formulated to provide a contact angle with the peelable substrate or the dielectric layer(s) of between about 100° and about 165°.

In an embodiment, the ink-jet ink compositions and methods allowing for a continuous or semi-continuous ink-jet printing of a PCB (and/or FPC and/or HDI circuits) comprising the infrastructure elements, can be patterned by expelling droplets of the liquid ink-jet ink provided herein from an orifice one-at-a-time, as the print-head (or the substrate) is maneuvered, for example in two (X-Y) (it should be understood that the print head can also move in the Z axis) dimensions at a predetermined distance above the substrate or any subsequent layer. The ink-jet print heads provided used in the methods described herein can provide a minimum layer film thickness equal to or less than about 3 μm-10,000 μm

In an embodiment, the volume of each droplet of the conductive ink, and/or the dielectric ink, can range from 0.5 to 300 picoLiter (pL), for example 1-4 pL and depended on the strength of the driving pulse and the properties of the ink. The waveform to expel a single droplet can be a 10V to about 70 V pulse, or about 16V to about 20V, and can be expelled at frequencies between about 5 kHz and about 20 kHz.

The dielectric ink composition comprises in an embodiment; active components of a polymer capable of undergoing photoinitiation using the photoinitiators provided herein. Such live monomer, live oligomer, live polymer or their combination can be for example, multifunctional acrylates, can be for example, at least one of: 1,2-ethanediol diacrylate, 1,3-propanediol diacrylate, 1,4-butanediol diacrylate, 1,6-hexanediol diacrylate, dipropylene glycol diacrylate, neopentyl glycol diacrylate, ethoxylated neopentyl glycol diacrylate, propoxylated neopentyl glycol diacrylate, tripropylene glycol diacrylate, bisphenol-A-diglycidyl ether diacrylate, hydroxypivalic acid neopentanediol diacrylate, ethoxylated bisphenol-A-diglycidyl ether diacrylate, polyethylene glycol diacrylate, trimethylolpropane triacrylate, ethoxylated trimethylolpropane triacrylate, propoxylated trimethylolpropane triacrylate, propoxylated glycerol triacrylate, tris(2-acryloyloxyethyl)isocyanurate, pentaerythritol triacrylate, ethoxylated pentaerythritol triacrylate, pentaerythritol tetraacrylate, ethoxylated pentaerythritol tetraacrylate, ditrimethylolpropane tetraacrylate, dipentaerythritol pentaacrylate and dipentaerythritol hexaacrylate.

The dielectric ink can further comprise: a cross-linking agent (other than the polymer forming the dielectric constituent), a monomer, co-monomer, a co-oligomer, co-polymer or a composition comprising one or more of the foregoing. Likewise, the oligomer and/or polymer backbone can be induced to form cross links by contacting the polymer with an agent (in other words, the cross-linking agent) that will form free radicals on the backbone, thereby allowing for crosslinking sites. In an embodiment, the cross-linking agent, co-monomer, co-oligomer, co-polymer or a composition comprising one or more of the foregoing can be a part, or configured to form a solution, emulsion, gel or suspension within the continuous phase.

In an embodiment, the continuous phase used in the PCBs (FPCs and HDI circuits) fabricated using the disclosed methods comprising the infrastructure elements can comprise: multifunctional acrylate monomer, oligomer, polymer or their combination; a cross-linking agent; and a radical photoinitiator, and can be partially or entirely soluble in the continuous phase.

Initiating the polymerization dielectric resin backbone can be done using an initiator, for example benzoyl peroxide (BP) and other peroxide-containing compounds. The term “initiator” as used herein generally refers to a substance that initiates a chemical reaction, specifically any compound which initiates polymerization, or produces a reactive species which initiates polymerization, including, for example and without limitation, co-initiators and/or photoinitiator(s).

In another embodiment, composition comprises active components of a polymer capable of undergoing photoinitiation using a photoinitiator. Such live monomer, live oligomer, live polymer or their combination capable of undergoing photoinitiation can be for example, multifunctional acrylates, for example a multifunctional acrylate that can be multifunctional acrylate is selected from the group consisting of 1,2-ethanediol diacrylate, 1,3-propanediol diacrylate, 1,4butanediol diacrylate, 1,6-hexanediol diacrylate, dipropylene glycol diacrylate, neopentyl glycol diacrylate, ethoxylated neopentyl glycol diacrylate, propoxylated neopentyl glycol diacrylate, tripropylene glycol diacrylate, bisphenol-A-diglycidyl ether diacrylate, hydroxypivalic acid neopentanediol diacrylate, ethoxylated bisphenol-A-diglycidyl ether diacrylate, polyethylene glycol diacrylate, trimethylolpropane triacrylate, ethoxylated trimethylolpropane triacrylate, propoxylated trimethylolpropane triacrylate, propoxylated glycerol triacrylate, tris(2-acryloyloxyethyl)isocyanurate, pentaerythritol triacrylate, ethoxylated pentaerythritol triacrylate, pentaerythritol tetraacrylate, ethoxylated pentaerythritol tetraacrylate, ditrimethylolpropane tetraacrylate, dipentaerythritol pentaacrylate and dipentaerythritol hexaacrylate.

Photoinitiators that can be used with the multifunctional acrylates described herein can be, for example radical photoinitiator. These radical photoinitiators can be, for example Irgacure® 500 from CIBA SPECIALTY CHEMICAL and Darocur® 1173, Irgacure® 819, Irgacure® 184, TPOL (ethyl(2,4,6,trimethyl benzoil) phenyl phosphinate) benzophenone and acetophenone compounds and the like. For example, the radical photoinitiator can be cationic photo-initiator, such as mixed triarylsulfonium hexafluoroantimonate salts. Another example of the radical photoinitiator used in the active continuous phase described herein, can be 2-ispropylthioxanthone.

The terms “live monomer”, “live oligomer”, “polymer” or their counterparts (comonomer e.g.,) combination refers in an embodiment to a monomer, a short group of monomers or a polymer having at least one functional group capable of forming a radical reaction (in other words, the reaction can be continued and is not otherwise terminated by an end-group).

The cross-linking agent used in the compositions, systems and methods described herein, for forming the PCB comprising the infrastructure elements can be, for example, a primary or secondary polyamine and adducts thereof, or in another example, an anhydride, a polyamide, a C₄-C₃₀ polyoxyalkylene in which the alkylene groups each independently comprise 2 to 6 carbon atoms, or a composition comprising one or more of the foregoing.

The suspension may require the presence of a surfactant and optionally a cosurfactants. The surfactants and/or cosurfactants may be cationic surfactants, anionic surfactants, non-ionic surfactant and amphiphilic copolymers, such as block copolymers.

Moreover, the dielectric layer portion can have a substantially uniform thickness throughout, thereby creating a substantially planar (e.g., flat) surface for receiving an additional conductive circuit pattern. The dielectric layer may be an UV curable adhesive or other polymer material. In an embodiment, the dielectric ink comprises a UV curable polymer. Other dielectric polymers such as, for example, polyester (PES), polyethylene (PE), polyvinyl alcohol (PVOH) and poly-methyl methacrylate (PMMA), Poly(vinylpirrolidone) (PVP, water soluble and may be beneficial not to clog the print head orifice). Other dielectric materials can be photoresistive polymers, for example, SU-8 based polymers, polymer-derived ceramics or their combination and copolymers can also be used.

The systems used to implement the methods provided herein, can further comprises a computer aided manufacturing (“CAM”) module, the module comprising a data processor, a nonvolatile memory, and a set of executable instructions stored on the non-volatile memory, which. when executed are configured to cause the processor to: receive a 3D visualization file representing the printed circuit board comprising the infrastructure elements; generate a library of files, each file represents at least one, substantially 2D layer for printing the printed circuit board comprising the infrastructure elements, creating a substantially 2D representation image pattern of the substantially 2D layer comprising the infrastructure elements; receive a selection of parameters related to the printed circuit board comprising the infrastructure elements; and alter the file representing the at least one, substantially 2D layer based on at least one of the selection of parameters, wherein the CAM module is configured to control each of the first and second print heads.

Accordingly, the step of using the first print head is preceded by a step of: using the CAM module, obtaining a generated file representing a first, substantially 2D layer of the printed circuit board comprising the infrastructure elements for printing, the 2D layer comprising a pattern representative of the dielectric ink, and the conductive ink, wherein the parameters used in the selection of parameters related to the printed circuit board comprising the infrastructure element comprise: the type of infrastructure element, the heating characteristics of integrated circuit (IC) configured to couple to the infrastructure element and which may act as a heat source sought to be dissipated, the IC packaging requirement, the heat transfer coefficient of at least one of: the dielectric, and conductive ink compositions after curing and sintering respectively, or a combination of parameters comprising one or more of the foregoing.

The term “comprising” and its derivatives, as used herein, are intended to be open ended terms that specify the presence of the stated features, elements, components, groups, integers, and/or steps, but do not exclude the presence of other unstated features, elements, components, groups, integers and/or steps. The foregoing also applies to words having similar meanings such as the terms, “including”, “having” and their derivatives.

All ranges disclosed herein are inclusive of the endpoints, and the endpoints are independently combinable with each other. “Combination” is inclusive of blends, mixtures, alloys, reaction products, and the like. The terms “a”, “an” and “the” herein do not denote a limitation of quantity, and are to be construed to cover both the singular and the plural, unless otherwise indicated herein or clearly contradicted by context. The suffix “(s)” as used herein is intended to include both the singular and the plural of the term that it modifies, thereby including one or more of that term (e.g., the source(s) includes one or more heart source). Reference throughout the specification to “one embodiment”, “another embodiment”, “an embodiment”, and so forth, when present, means that a particular element (e.g., feature, structure, and/or characteristic) described in connection with the embodiment is included in at least one example described herein, and may or may not be present in other examples. In addition, it is to be understood that the described elements may be combined in any suitable manner and/or order, in the various embodiments.

All ranges disclosed herein are inclusive of the endpoints, and the endpoints are independently combinable with each other. Furthermore, the terms “first,” “second,” and the like, herein do not denote any order, quantity, or importance, but rather are used to denote one element from another.

Likewise, the term “about” means that amounts, sizes, formulations, parameters, and other quantities and characteristics are not and need not be exact, but may be approximate and/or larger or smaller, as desired, reflecting tolerances, conversion factors, rounding off, measurement error and the like, and other factors known to those of skill in the art. In general, an amount, size, formulation, parameter or other quantity or characteristic is “about” or “approximate” whether or not expressly stated to be such.

Accordingly and in an embodiment, provided herein is an inkjet printing method for forming infrastructure element for an integrated circuit in a printed circuit board, the method comprising: providing a substrate; providing an ink jet printing system comprising: a first print head having: at least one aperture, a dielectric ink reservoir, and a first dispenser configured to supply the dielectric ink through the aperture; a second print head having: at least one aperture, a conductive ink reservoir, and a second dispenser configured to supply the conductive ink through the aperture; a conveyor, operably coupled to the first print head and to the second print head, configured to convey the substrate to the first and second print head; and a computer aided manufacturing (“CAM”) module, comprising: a processor; a non-volatile memory; and a set of executable instructions stored on the non-volatile memory configured, when executed to cause the processor to: receive a 3D visualization file representing the infrastructure element; using the 3D visualization file, generate a library comprising a plurality of files, each file representing a substantially 2D layer for printing of the infrastructure element; receive a selection of parameters related to the infrastructure element; and alter each of the substantially 2D layer file in the library based on at least one of the selection of parameters for printing at least one of a conducting portion and a dielectric portion of the infrastructure element; providing a dielectric ink composition and a conductive ink composition; using the CAM module, obtaining the generated file representing the plurality of substantially 2D layer of the infrastructure element for printing, the 2D layer comprising a pattern representative of the conductive inkjet ink and the dielectric inkjet ink, wherein the file obtained correspond to a first layer for printing; using the first print head, forming the pattern corresponding to the dielectric representation in the first layer of the infrastructure element for printing; curing the dielectric pattern; using the second print head, forming the pattern corresponding to the conductive representation in the first layer of the infrastructure element for printing; sintering the conductive pattern; and repeating the steps from obtaining the generated file, wherein the file obtained correspond to a subsequent layer to a precedent layer for printing, to the step of sintering the conductive layer to the completion of the library, wherein (i) the infrastructure element is at least one of a cooling pad, a heat-pipe, a condenser, a wick, a cooling platform, and a vapor chamber, (ii) the heat pipe is a 2-phase heat pipe, wherein (iii) the infrastructure element is a socket, (iv) the socket is at least partially disposed in the printed circuit board, wherein (v) the cooling pad extends basally at an angle of less than 80° relative to the apical surface's plane, wherein, (vi) the cooling platform is in direct contact with an external heat source, (vii) the external heat source is at least one of: a switch mode power integrated circuit, a dual in-line package (DIP) a Quad Flat Pack (QFP) package, a Thin Small Outline Package (TSOP), a Small Outline Integrated Circuit (SOIC) package, a Small Outline J-Lead (SOJ) package, a Plastic Leaded Chip Carrier (PLCC) package, a Wafer Level Chip Scale Package (WLCSP), a Mold Array Process-Ball Grid Array (MAPBGA) package, a Quad Flat No-Lead (QFN) package, and a Land Grid Array (LGA) package, a graphic processing unit (GPU), a central processing unit (CPU), and a light emitting diode (LED) assembly, wherein (viii) the printed circuit board is a multi-layered printed circuit board defining a hollow intermediate layer (ix) at least one of the cooling pad, the heat pipe, and the wick terminates at the hollow intermediate layer, wherein (x) the step of curing comprises at least one of heating, photobleaching, drying, depositing plasma, cross linking, annealing, and facilitating redox reaction, wherein (xi) sintering comprises at least one of heating and drying, wherein (xii) the parameters used in the selection of parameters related to the printed circuit board comprising the infrastructure element comprise: the type of infrastructure element, the physico-chemical characteristics of integrated circuit (IC) configured to couple to the infrastructure element, the IC packaging requirement, the heat transfer coefficient of at least the dielectric and conductive ink composition after curing and sintering respectively, or a combination of parameters comprising one or more of the foregoing, and further (xiii) a printed circuit board, a flexible printed circuit, a high-density interconnect circuit and their combination comprising the infrastructure element fabricated using the method of any one of the examples and embodiments disclosed herein.

The above examples and description have of course been provided only for the purpose of illustration, and are not intended to limit the disclosed technology in any way. As will be appreciated by the skilled person, the disclosed technology can be carried out in a great variety of ways, employing more than one technique from those described above, all without exceeding the scope of the invention.

1. An inkjet printing method for forming infrastructure element for an integrated circuit in a printed circuit board, the method comprising:
a) providing a substrate;
b) providing an ink jet printing system comprising:
i. a first print head having: at least one aperture, a dielectric ink reservoir, and a first dispenser configured to supply the dielectric ink through the aperture;
ii. a second print head having: at least one aperture, a conductive ink reservoir, and a second dispenser configured to supply the conductive ink through the aperture;
iii. a conveyor, operably coupled to the first print head and to the second print head, configured to convey the substrate to the first and second print head; and
iv. a computer aided manufacturing (“CAM”) module, comprising: a processor; a non-volatile memory; and a set of executable instructions stored on the non-volatile memory configured, when executed to cause the processor to: receive a 3D visualization file representing the infrastructure element being at least one of: a cooling pad, a heat-pipe, a condenser, a wick, a cooling platform, and a vapor chamber; using the 3D visualization file, generate a library comprising a plurality of files, each file representing a substantially 2D layer for printing of the infrastructure element; receive a selection of parameters related to the infrastructure element; and alter each of the substantially 2D layer file in the library based on at least one of the selection of parameters for printing at least one of a conducting portion and a dielectric portion of the infrastructure element;
c) providing a dielectric ink composition and a conductive ink composition;
d) using the CAM module, obtaining the generated file representing the plurality of substantially 2D layer of the infrastructure element for printing, the 2D layer comprising a pattern representative of the conductive inkjet ink and the dielectric inkjet ink, wherein the file obtained correspond to a first layer for printing;
e) using the first print head, forming the pattern corresponding to the dielectric representation in the first layer of the infrastructure element for printing;
f) curing the dielectric pattern;
g) using the second print head, forming the pattern corresponding to the conductive representation in the first layer of the infrastructure element for printing;
h) sintering the conductive pattern; and
i) repeating the steps from obtaining the generated file, wherein the file obtained correspond to a subsequent layer to a precedent layer for printing, to the step of sintering the conductive layer to the completion of the library; and wherein the printed circuit board is a multi-layered printed circuit board defining a hollow intermediate layer and wherein at least one of: the cooling pad, the heat pipe, and the wick terminates at the hollow intermediate layer.

2. (canceled)

3. The method of claim 1, wherein the heat pipe is a 2-phase heat pipe

4. The method of claim 1, wherein the infrastructure element is a socket.

5. The method of claim 4, wherein the socket is at least partially disposed in the printed circuit board.

6. The method of claim 1, wherein the cooling pad extends basally at an angle of less than 80° relative to the apical surface.

7. The method of claim 1, wherein the cooling platform is in direct contact with an external heat source.

8. The method of claim 7, wherein the external heat source is at least one of: a switch mode power integrated circuit, a dual in-line package (DIP) a Quad Flat Pack (QFP) package, a Thin Small Outline Package (TSOP), a Small Outline Integrated Circuit (SOIC) package, a Small Outline J-Lead (SOJ) package, a Plastic Leaded Chip Carrier (PLCC) package, a Wafer Level Chip Scale Package (WLCSP), a Mold Array Process-Ball Grid Array (MAPBGA) package, a Quad Flat NoLead (QFN) package, and a Land Grid Array (LGA) package, a graphic processing unit (GPU), and a central processing unit (CPU).

9. (canceled)

10. The method of claim 1, wherein the step of curing comprises at least one of heating, photobleaching, drying, depositing plasma, cross linking, annealing, and facilitating redox reaction.

11. The method of claim 1, wherein sintering comprises at least one of heating and drying.

12. The method of claim 1, wherein the parameters used in the selection of parameters related to the printed circuit board comprising the infrastructure element comprise: the type of infrastructure element, the physico-chemical characteristics of integrated circuit (IC) configured to couple to the infrastructure element, the IC packaging requirement, the heat transfer coefficient of at least the dielectric and conductive ink composition after curing and sintering respectively, or a combination of parameters comprising one or more of the foregoing.

13. A processor readable medium storing thereon a set of executable instructions configured, when executed to cause at least one processor to:
a) receive a 3D visualization file representing the infrastructure element, wherein the infrastructure element is at least one of a cooling pad, a heat-pipe, a condenser, a wick, a cooling platform, and a vapor chamber in a multi-layered printed circuit board defining a hollow intermediate layer;
b) using the 3D visualization file, generate a library comprising a plurality of files, each file representing a substantially 2D layer for printing of the infrastructure element;
c) receive a selection of parameters related to the infrastructure element; and
d) alter each of the substantially 2D layer file in the library based on at least one of the selection of parameters for printing at least one of a conducting portion and a dielectric portion of the infrastructure element, wherein upon completion of printing of the substantially 2D layer file in the library, the at least one of: the cooling pad, the heat pipe, and the wick terminates at the hollow intermediate layer.

14. At least one of a printed circuit board, a flexible printed circuit, a high-density interconnect circuit and their combination comprising the infrastructure element fabricated using the method of claim 1.
